(19) United States
(12) Patent Application Publication
(10) Pub. No.: US 2012/0018084 A1
(43) Pub. Date: Jan. 26, 2012

(54) Printed Circuit Board Assembly Manufacturing Device And Method

(75) Inventors: Kyung Woon Jang, Suwon-si (KR); Seungbae Park, Binghamton, NY (US); Young Jun Moon, Hwaseong-si (KR); Soon Min Hong, Seoul (KR); Chang-kyu Chung, Suwon-si (KR); Dae Jung Kim, Guro-gu (KR); Sang il Hong, Suwon-si (KR)

(73) Assignee: SAMSUNG ELECTRONICS CO., LTD., Suwon-si (KR)

(21) Appl. No.: 13/177,064

(22) Filed: Jul. 6, 2011

(30) Foreign Application Priority Data
Jul. 20, 2010 (KR) 10-2010-0070116

(51) Int. Cl. H05K 7/00

(52) U.S. Cl. 156/230; 361/760; 156/499; 156/383

(57) ABSTRACT

Disclosed herein is a printed circuit board assembly manufacturing device and method of manufacturing a printed circuit board assembly. The printed circuit board assembly manufacturing device may include a fusing unit configured to cure a conductive adhesive used to fix electronic components having different heights to a printed circuit board. The fusing unit may be configured to cure the conductive adhesive while simultaneously applying pressure to the electronic components having different heights.

### CROSS-REFERENCE TO RELATED APPLICATION

This application claims priority under 35 U.S.C. §119 to Korean Patent Application No. 2010-0070116, filed on Jul. 20, 2010 in the Korean Intellectual Property Office (KIPO), the entire contents of which is incorporated herein by reference.

### BACKGROUND

1. Field

Example embodiments relate to a process of bonding components to a printed circuit board using an anisotropic conductive film.

2. Description of the Related Art

Surface Mount Technology (SMT) is a technology for connecting various components to a Printed Circuit Board (PCB). However, as trends towards light-weight, thin, short, and miniaturized electronic products have developed, if a conventional SMT process is used, a defect rate is gradually increased.

### SUMMARY

Example embodiments provide a printed circuit board assembly manufacturing device and method in which uniform pressure is supplied when components are connected to a printed circuit board using an anisotropic conductive film.

Additional aspects of the invention will be set forth in part in the description which follows and, in part, will be obvious from the description, or may be learned by practice of example embodiments.

In accordance with example embodiments, a printed circuit board assembly manufacturing device may include a stage and a fusing unit. In example embodiments, the stage may be configured to support a printed circuit board and the printed circuit board may include electronic components having different heights bonded to the printed circuit board by a conductive adhesive. In example embodiments the fusing unit may be configured to simultaneously apply pressure and heat to the printed circuit board to cure the conductive adhesive.

In accordance with example embodiments, a printed circuit board assembly manufacturing device may include a stage and a fusing unit. In example embodiments, the stage may be provided with a layer configured to support a printed circuit board and the printed circuit board may include electronic components having different heights bonded to upper and lower surfaces thereof by conductive adhesives. In example embodiments, the fusing unit may be configured to cure the respective conductive adhesives while simultaneously applying pressure to the electronic components having different heights bonded to the upper and lower surfaces of the printed circuit board, wherein the layer includes a flexible material.

In accordance with example embodiments, a printed circuit board assembly manufacturing device may include a clamping unit configured to fix a printed circuit board. In example embodiments, the printed circuit board may have an upper and lower surface. The upper surface may include a first plurality of electronic components having different heights and the first plurality of electronic components may be bonded thereon by a first adhesive. The lower surface may include a second plurality of electronic components having different heights and the second plurality of electronic components may be bonded thereon by a second conductive adhesive. In example embodiments, the printed circuit board assembly manufacturing device may further include a first fusing unit configured to cure the first conductive adhesive by simultaneously applying pressure and heat to the first plurality of electronic components and a second fusing unit configured to cure the second conductive adhesive by simultaneously applying pressure and heat to the second plurality of electronic components.

In accordance with example embodiments, a method manufacturing a printed circuit board assembly may include attaching a conductive adhesive to a printed circuit board. In example embodiments, the conductive adhesive may include a release tape and electronic components having different heights may be bonded to the printed circuit board by removing the release paper from the conductive adhesive. In example embodiments, pressure and heat may be simultaneously applied to the electronic components having different heights via elastic particles to cure the conductive adhesive.

In accordance with example embodiments, a method of manufacturing a printed circuit board assembly may include attaching a conductive adhesive to a printed circuit board, bonding electronic components having different heights to the printed circuit board by removing a release paper from the conductive adhesive, and simultaneously applying pressure and heat to the electronic components having different heights through one of a pneumatic and a hydraulic pressure supply unit to cure the conductive adhesive.

In accordance with example embodiments, a method of manufacturing a printed circuit board assembly may include attaching conductive adhesives to upper and lower surfaces of a printed circuit board, bonding electronic components having different heights to the upper and lower surfaces of the printed circuit board by removing a release paper from each of the conductive adhesives, simultaneously applying pressure and heat to the electronic components having different heights bonded to the upper surface of the printed circuit board through a fusing unit so as to cure the conductive adhesive on the upper surface of the printed circuit board, and simultaneously applying pressure and heat to the electronic components having different heights bonded to the lower surface of the printed circuit board through a layer made of a flexible material so as to cure the conductive adhesive on the lower surface of the printed circuit board.

In accordance with example embodiments, a method of manufacturing a printed, circuit board assembly may include bonding electronic components having different heights to upper and lower surfaces of the printed circuit board using conductive adhesives, simultaneously applying pressure and heat, to the electronic components having different heights bonded to the upper surface of the printed circuit board through a first fusing unit to cure the conductive adhesive on the upper surface of the substrate, and simultaneously applying pressure and heat to the electronic components having different heights bonded to the lower surface of the printed circuit board through a second fusing unit to cure the conductive adhesive on the lower surface of the substrate.

In accordance with example embodiments, a printed circuit board assembly may include a printed circuit board, a conductive adhesive on the printed circuit board, and electronic components having different heights bonded to the printed circuit board, wherein the conductive adhesive is between the printed circuit board and the electronic components and is comprised of a curable material that is cured while simultaneously applying pressure and heat to the electronic components having different heights.

In accordance with example embodiments, a printed circuit board assembly manufacturing device may include a stage, a printed circuit board supported by the stage, electronic components having different heights pre-bonded to the printed circuit board by a conductive adhesive, and a fusing unit to cure the conductive adhesive while simultaneously applying pressure to the electronic components having the different heights.

The fusing unit may include a buffer member to cover the electronic components having the different heights, and elastic particles to apply uniform pressure to the electronic components having the different heights together with the buffer member.

The fusing unit may further include a housing provided with a cavity in which the elastic particles are provided, and a pressure member movably provided on the housing, and the pressure member may push the elastic particles downward.

The elastic particles and the buffer member may be deformed to shapes corresponding to the electronic components having different heights, and fill gaps between the electronic components having different heights.

The printed circuit board assembly manufacturing device may further include heaters provided in any one of the housing and the pressure member to supply heat to the conductive adhesive.

The conductive adhesive may include an Anisotropic Conductive Film (ACF).

The buffer member may include a polymer sheet or a polymer film.

The fusing unit may include a buffer member to cover the electronic components having the different heights, and a pneumatic pressure supply unit to apply uniform pressure to the electronic components having the different heights together with the buffer member.

The fusing unit may further include a housing provided with a designated cavity, and the pneumatic pressure supply unit may supply pneumatic pressure to the cavity of the housing.

The fusing unit may include a buffer member to cover the electronic components having different heights, and a hydraulic pressure supply unit to apply uniform pressure to the electronic components having different heights together with the buffer member.

The fusing unit may further include a housing provided with a designated cavity, and the hydraulic pressure supply unit may supply hydraulic pressure to the cavity of the housing.

In accordance with example embodiments, a printed circuit board assembly manufacturing device may include a stage provided with a layer made of a flexible material, a printed circuit board supported by the layer of the stage, electronic components having different heights pre-bonded to both surfaces of the printed circuit board by conductive adhesives, respectively, and a fusing unit to cure the respective conductive adhesives while simultaneously applying pressure to the electronic components having the different heights pre-bonded to both surfaces of the printed circuit board.

When the fusing unit applies pressure to the electronic components having the different heights pre-bonded to one surface of the printed circuit board, the layer of the stage may be deformed to shapes corresponding to the electronic components having the different heights pre-bonded to the other surface of the printed circuit board.

A Teflon sheet may be provided between the layer of the stage and the electronic components having different heights.

In accordance with example embodiments, a printed circuit board assembly manufacturing device may include a clamping unit to fix a printed circuit board, electronic components having different heights pre-bonded to both surfaces of the printed circuit board by conductive adhesives, respectively, a first fusing unit to cure the corresponding conductive adhesive while simultaneously applying pressure to the electronic components having the different heights pre-bonded to one surface of the printed circuit board, and a second fusing unit to cure the corresponding conductive adhesive while simultaneously applying pressure to the electronic components having the different heights pre-bonded to the other surface of the printed circuit board.

In accordance with example embodiments, a printed circuit board assembly manufacturing method includes pre-attaching a conductive adhesive to a printed circuit board, pre-bonding electronic components having different heights to the printed circuit board by removing a release paper from the conductive adhesive, and simultaneously applying pressure to the electronic components having the different heights through elastic particles so as to cure the conductive adhesive.

The elastic particles may be deformed to shapes corresponding to the electronic components having different heights, and fill gaps between the electronic components having different heights.

Heaters may supply heat to the conductive adhesive.

In accordance with example embodiments, a printed circuit board assembly manufacturing method may include pre-attaching a conductive adhesive to a printed circuit board, pre-bonding electronic components having different heights to the printed circuit board by removing a release paper from the conductive adhesive, and simultaneously applying pressure to the electronic components having the different heights through a pneumatic or hydraulic pressure supply unit so as to cure the conductive adhesive.

In accordance with example embodiments, a printed circuit board assembly manufacturing method may include pre-attaching conductive adhesives to both surfaces of a printed circuit board, respectively, pre-bonding electronic components having different heights to both surfaces of the printed circuit board by removing a release paper from each of the conductive adhesives, simultaneously applying pressure to the electronic components having the different heights pre-bonded to one surface of the printed circuit board through a fusing unit so as to cure the corresponding conductive adhesive, and simultaneously applying pressure to the electronic components having the different heights pre-bonded to the other surface of the printed circuit board through a layer made of a flexible material so as to cure the corresponding conductive adhesive.

In accordance with example embodiments, a printed circuit board assembly manufacturing method may include pre-bonding electronic components having different heights to both surfaces of the printed circuit board using conductive adhesives, respectively, simultaneously applying pressure to the electronic components having the different heights pre-bonded to one surface of the printed circuit board through a first fusing unit so as to cure the corresponding conductive adhesive, and simultaneously applying pressure to the electronic components having different heights pre-bonded to the other surface of the printed circuit board through a second fusing unit so as to cure the corresponding conductive adhesive.

In accordance with example embodiments, a printed circuit board assembly may include a printed circuit board, a conductive adhesive attached to the printed circuit board, and electronic components having different heights bonded to the printed circuit board, wherein the conductive adhesive is cured while simultaneously applying pressure to the electronic components having the different heights.

### BRIEF DESCRIPTION OF THE DRAWINGS

These and/or other aspects of the invention will become apparent and more readily appreciated from the following description of example embodiments, taken in conjunction with the accompanying drawings of which:

FIG. 1 is a view schematically illustrating a configuration of a printed circuit board assembly manufacturing device in accordance with example embodiments;

FIG. 2 is a view schematically illustrating pre-bonding of a printed circuit board assembly using a printed circuit board assembly manufacturing device in accordance with example embodiments;

FIG. 3 is a view schematically illustrating complete bonding of the printed circuit board assembly using a printed circuit board assembly manufacturing device in accordance with example embodiments;

FIG. 4 is a view schematically illustrating a printed circuit board assembly after the bonding of the printed circuit board assembly using a printed circuit board assembly manufacturing device in accordance with example embodiments;

FIG. 5 is a view illustrating a fusing unit in accordance with example embodiments;

FIG. 6 is a view illustrating a manufacturing process of a printed circuit board assembly using the fusing unit of FIG. 5;

FIG. 7 is a view illustrating a printed circuit board assembly manufacturing device in accordance with example embodiments;

FIG. 8 is a view illustrating a manufacturing process of a printed circuit board assembly using the printed circuit board assembly manufacturing device of FIG. 7;

FIG. 9 is a view illustrating a printed circuit board assembly manufacturing device in accordance with example embodiments; and

FIG. 10 is a view illustrating a manufacturing process of a printed circuit board assembly using the printed circuit board assembly manufacturing device of FIG. 9.

### DETAILED DESCRIPTION

Example embodiments will be described more fully hereinafter with reference to the accompanying drawings, in which example embodiments are shown. The present invention may, however, be embodied in many different forms and should not be construed as limited to example embodiments set forth herein. Rather, example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made in detail to example embodiments as illustrated in the accompanying drawings, wherein like reference numerals refer to like elements throughout.

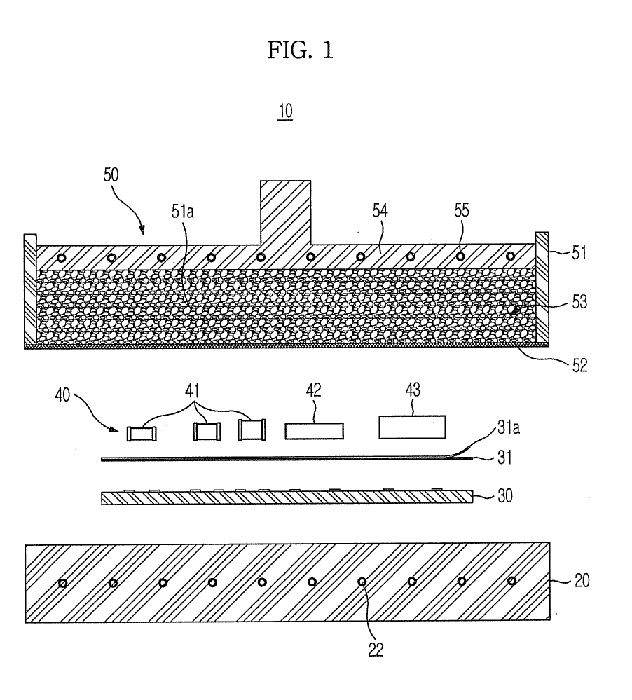

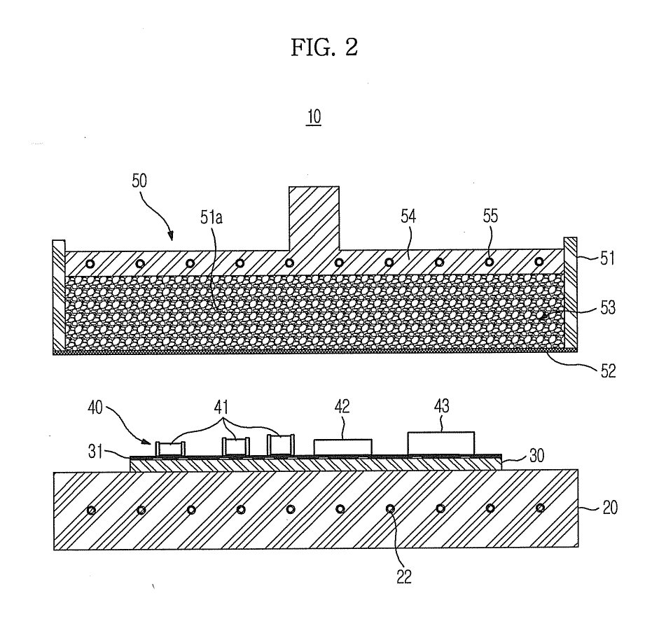

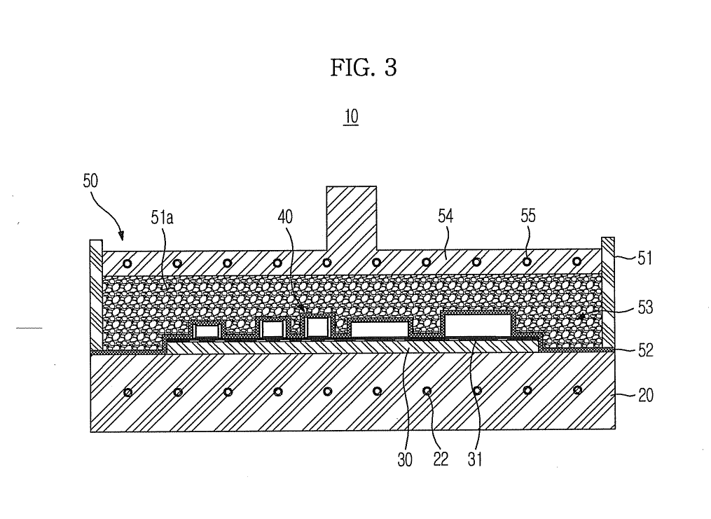

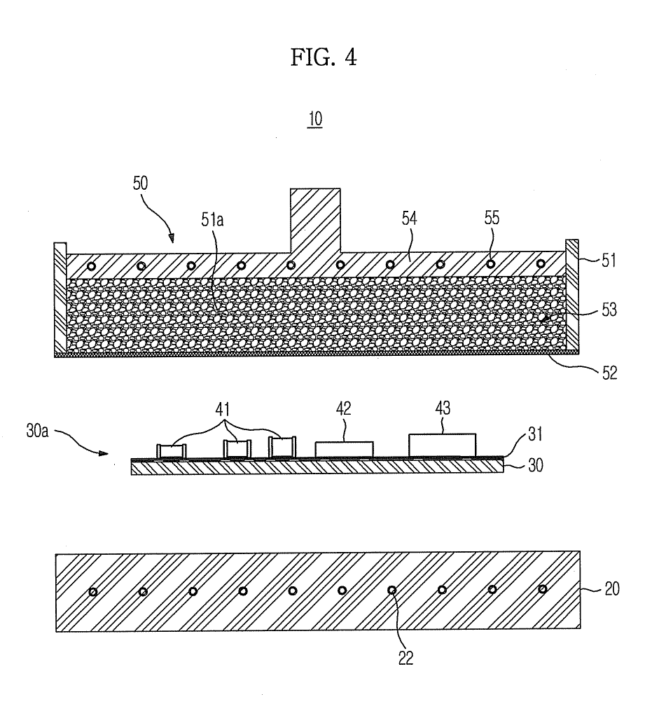

FIG. 1 is a view schematically illustrating a configuration of a printed circuit board assembly manufacturing device in accordance with example embodiments, FIG. 2 is a view schematically illustrating pre-bonding of a printed circuit board assembly using the printed circuit board assembly manufacturing device in accordance with example embodiments, FIG. 3 is a view schematically illustrating complete bonding of the printed circuit board assembly using the printed circuit board assembly manufacturing device in accordance with example embodiments, and FIG. 4 is a view schematically illustrating the printed circuit board assembly after the bonding of the printed circuit board assembly using the printed circuit board assembly manufacturing device of example embodiments.

As shown in FIGS. 1 to 4, a printed circuit board assembly manufacturing device 10 may include a stage 20 and a fusing unit 50. In example embodiments, the stage 20 and the fusing unit 50 may be used to secure a connection between various electronic components 40 and a printed circuit board 30. As shown in FIGS. 1-4, the various electronic components may be initially bonded to the printed circuit board 30 via an adhesive 31 that may or may not be conductive.

The stage 20 may be made of a metal material and may be formed in a flat shape. The printed circuit board 30 may be supported by the stage 20. Further, the stage 20 may include heaters 22. The heaters 22 may supply heat required to cure the conductive adhesive 31.

The printed circuit board 30 may serve as a substrate to electrically connect the electronic components 40 using signal lines or conductive lines obtained by wet etching.

The conductive adhesive 31 may include any adhesive used to bond the components 40 to the printed circuit board 30, for example, an anisotropic conductive film, a non-conductive paste, or a resin containing solder. The anisotropic conductive film may be a film type adhesive in which conductive particles are dispersed in a resin, and the non-conductive paste may be a paste type adhesive which does not contain conductive particles. Both the anisotropic conductive film and the non-conductive paste may be used to connect a substrate to another substrate or to connect components to a substrate. That is, the conductive adhesive 31 may be used to connect the various electronic components 40 to the printed circuit board 30.

The various electronic components 40 may be mounted on the printed circuit board 30. The various electronic components 40 may have different heights. For example, the various electronic components 40 may include RLC elements 41, a flip chip 42, and an IC package 43 mounted on the printed circuit board 30 and the RLC elements 41, the flip chip 42, and the IC package 43 may have different heights.

The fusing unit 50 may include a housing 51, a buffer member 52, elastic particles 53, a pressure member 54, and heaters 55. The fusing unit 50 may supply heat and pressure to the conductive adhesive 31, thereby curing the conductive adhesive 31.

The housing 51 may include a designated cavity 51a formed therein. Further, the housing 51 may be configured to move in the vertical direction, and thus may be seated on the stage 20.

In example embodiments, the buffer member 52 may be provided at an opening of the housing 51 to form a boundary of the cavity 51a enclosed by the housing 51. The buffer member 52 may include a polymer sheet or film which may be easily deformed.

In example embodiments, the buffer member 52 may be made of a material which has excellent thermal conductivity and resistance to heat and high temperature. Thus, the buffer member 52 may efficiently transmit heat and pressure. Further, the buffer member 52 may be made from a rubber-based material having elasticity and resilience, thus the buffer member 52 may be reusable. Further, the buffer member 52 may be made of a proper material in terms of thickness and elongation so that the buffer member 52 may be easily deformed to shapes corresponding to the electronic components 40.

In example embodiments, the elastic particles 53 may fill the cavity 51a of the housing 51. The elastic particles 53 may be sufficiently small to efficiently fill gaps between the electronic components 40 and to be easily deformed to the shapes corresponding to the electronic components 40. The elastic particles 53 may have a size of several μm to several mm. Further, in order to be reusable, the elastic particles 53 may be made of a rubber-based material having elasticity and resilience.

In example embodiments, the pressure member 54 may be movably installed on/in the housing 51. The pressure member 54 may be provided on the elastic particles 53 and may push the elastic particles 53 downward. In example embodiments, the buffer member 52 may be expanded downward together with the elastic particles 53. Thereby, the elastic particles 53 and the buffer member 52 provide a designated pressure to the conductive adhesive 31. Here, the pressure supplied from the pressure member 54 may be about 1˜7 MPa.

The heaters 55 may be provided in the housing 51 and/or the pressure member 54. Although FIG. 1 illustrates that the heaters 55 are installed in the pressure member 54, the installation position of the heaters 55 is not limited thereto. The heaters 55 may provide heat to the conductive adhesive 31.

Hereinafter, a process of manufacturing a printed circuit board assembly using the printed circuit board assembly manufacturing device in accordance with example embodiments will be described.

As shown in FIG. 2, the printed circuit board 30 may be placed on the stage 20. In example embodiments, the conductive adhesive 31 may be pre-attached to the printed circuit board 30. Here, in order to increase adhesive force between the conductive adhesive 31 and the printed circuit board 30, heat of a temperature of about 50˜80° C. may be supplied.

The various electronic components 40 may be mounted on the printed circuit board 30 to which the conductive adhesive 31 is attached. In order to maintain bonding of the various electronic components 40 to the printed circuit board 30, a release paper 31a may be removed from the conductive adhesive 31 prior to mounting of the various electronic components 40 on the printed circuit board 30. The electronic components 40 may be mounted on the printed circuit board 30 using a conventional Surface Mount Technology (SMT).

Thereafter, the fusing unit 50 supplies heat and pressure to the conductive adhesive 31, thereby allowing the various electronic components 40 to be completely mounted on the printed circuit board 30. The conductive adhesive 31 may be cured by the supplied heat and pressure, thereby allowing the various electronic components 40 to be completely mounted on the printed circuit board 30.

Particularly, the fusing unit 50 is advantageous in that it supplies relatively uniform pressure to the various electronic components 40 having different heights. In detail, as shown in FIG. 3, if the fusing unit 50 supplies heat and pressure to the printed circuit board 30 to which the various electronic components 40 are bonded, the housing 51 descends and is seated on the stage 20. Here, the pressure member 54 pushes the elastic particles 53 downward, and thereby the buffer member 52 covers the various electronic components 40. Then, the elastic particles 53 fill gaps between the various electronic components 40. That is, the buffer member 52 and the elastic particles 53 are deformed to the shapes corresponding to the various electronic components 40, thereby allowing pressure supplied from the pressure member 54 to be uniformly applied to the various electronic components 40 having different heights. Therefore, defects of the printed circuit board 30, such as warpage, may be prevented or reduced.

In example embodiments, the pressure member 54 may supply pressure and the heaters 22 and 55 may supply heat. For example, the pressure member 54 may supply pressure and the heaters 22 and 55 may supply heat simultaneously. Consequently, the conductive adhesive 31 may be cured by the supplied heat and pressure, thereby allowing the various electronic components 40 to be completely fused to the printed circuit board 30.

Thereafter, as shown in FIG. 4, the fusing unit 50 may be separated from the stage 20, thereby completing a printed circuit board assembly 30a. The fusing unit 50 may be restored to its original state and may be reusable in the above process.

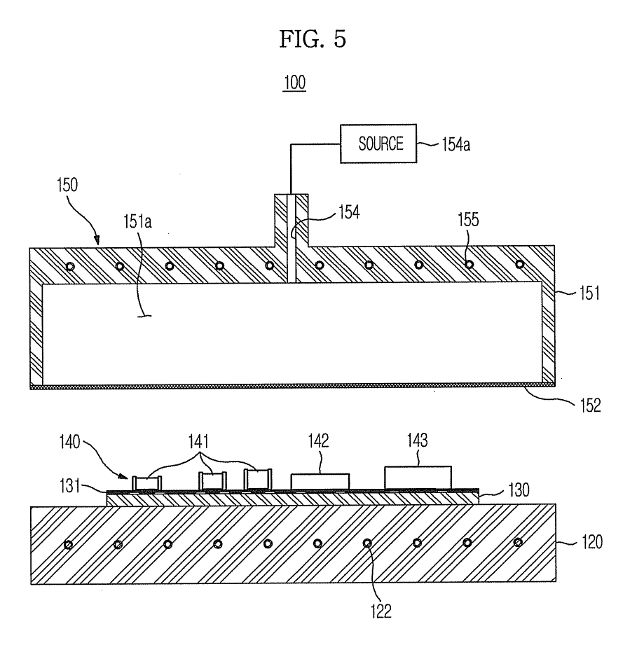

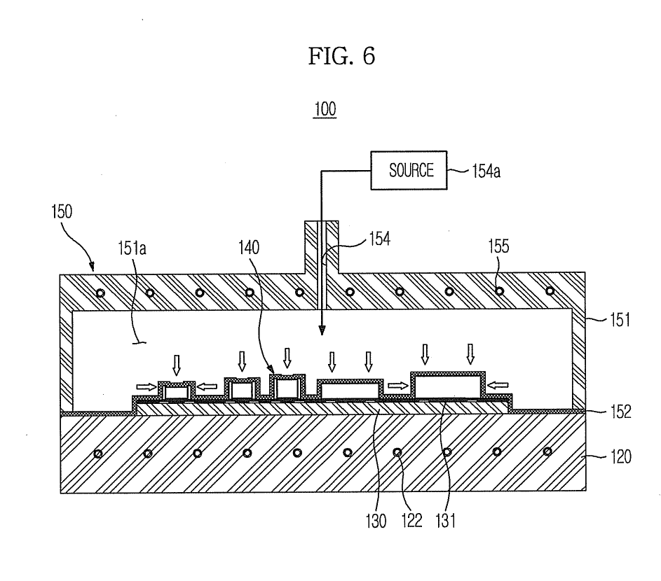

FIG. 5 is a view illustrating a fusing unit in accordance with example embodiments, and FIG. 6 is a view illustrating a manufacturing process of a printed circuit board assembly using the fusing unit of FIG. 5. Hereinafter, some parts illustrated in FIGS. 5 and 6 which are different from those in the embodiment of FIGS. 1 to 4 will be described in more detail.

As shown in FIGS. 5 and 6, a fusing unit 150, in accordance with example embodiments, may include a housing 151, a buffer member 152, a pneumatic pressure supply unit 154, and heaters 122 and 155. Such a fusing unit 150 may supply heat and pressure to a conductive adhesive 131, for example, an anisotropic conductive film, thereby curing the conductive adhesive 131.

The housing 151 may include a designated cavity 151a formed therein. Further, the housing 151 may be provided movably in the vertical direction, and thus may be seated on a stage 120.

The buffer member 152 may be provided at one side of the housing 151 to form a boundary of the cavity 151a in the housing 151. The buffer member 152 may include a polymer sheet or film which may be easily deformed.

The pneumatic pressure supply unit 154 may supply pneumatic pressure to the cavity 151a of the housing 151. The pneumatic pressure supply unit 154 may be connected to a pneumatic pressure source 154a. When the pneumatic pressure supply unit 154 supplies pneumatic pressure to the cavity 151a of the housing 151, the buffer member 152 is deformed to shapes corresponding to various electronic components 140, for example, RLC elements 141, a flip chip 142, and an IC package 143. Thereby, the pneumatic pressure supply unit 154 may supply relatively uniform pressure to the various electronic components 140. In example embodiments, pressure supplied from the pneumatic pressure unit 154 may be about 10˜70 atm. Such a pressure is similar to a pressure level used in a general bonding process using the conductive adhesive 131.

The heaters 122 and 155 may be provided in the housing 151, and supply heat to the conductive adhesive 131.

Hereinafter, a process of manufacturing a printed circuit board assembly using the fusing unit in accordance with example embodiments, as shown in FIGS. 5 and 6, will be described.

With reference to FIGS. 1 to 6, the printed circuit board 130 may be placed on the stage 120 and a conductive adhesive 131 may be attached to the printed circuit board 130. A release paper (similar to the release paper 31a of FIG. 1) may be removed from the conductive adhesive 131, and the electronic components 140 may be mounted on the printed circuit board 130 as has been previously described.

In example embodiments, the fusing unit 150 may supply heat and pressure to the conductive adhesive 131, thereby allowing the various electronic components 140 to be completely mounted on the printed circuit board 130. Particularly, the fusing unit 150 supplies relatively uniform pressure to the various electronic components 140 having different heights. In detail, as shown in FIG. 6, if the fusing unit 150 supplies heat and pressure to the printed circuit board 130 to which the various electronic components 140 are bonded, the housing 151 descends and is seated on the stage 120. In example embodiments, the pneumatic pressure supply unit 154 may supply pneumatic pressure to the cavity 151a of the housing 151, and thus the buffer member 152 may cover the various electronic components 140 and may be deformed to shapes corresponding to the various electronic components 140, thereby allowing the pressure supplied to the cavity 151a of the housing 151 to be uniformly applied to the various electronic components 140 having different heights.

Simultaneously with supply of heat and pressure from the pneumatic pressure supply unit 154, the heaters 122 and 155 supply heat, and the conductive adhesive 131 is cured by the supplied heat and pressure, thereby allowing the various electronic components 140 to be completely fused to the printed circuit board 130.

Although FIGS. 5 and 6 illustrate that pneumatic pressure may be supplied to the cavity 151a of the housing 151, pressure supplied to the cavity 151a is not limited thereto. That is, a hydraulic pressure supply unit may be provided on the housing 151 to supply hydraulic pressure to the cavity 151a of the housing 151 so as to allow the buffer member 152 to uniformly pressurize the various electronic components 140 having different heights. Thus, in FIGS. 5 and 6, elements 154 and 154a may be also be considered as representing a hydraulic pressure supply unit and a hydraulic pressure source, respectively.

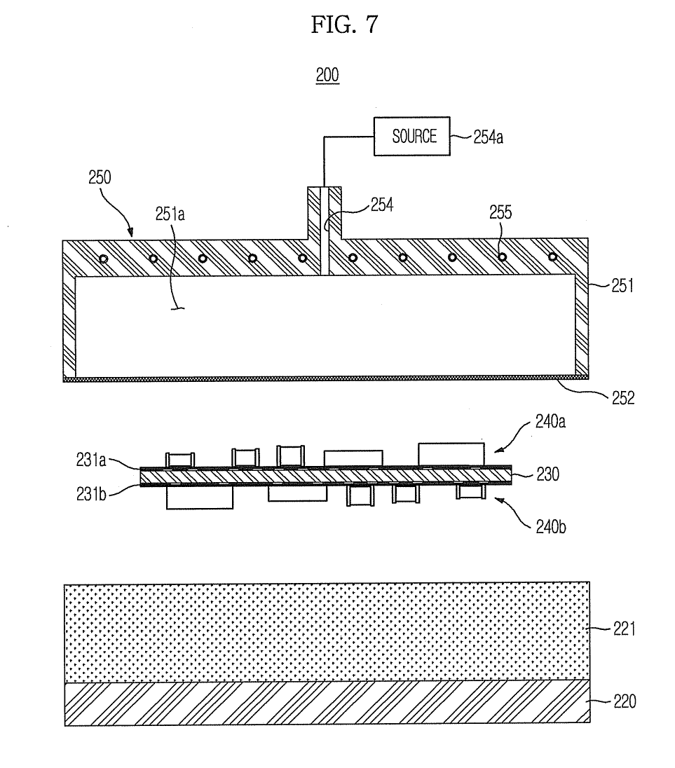

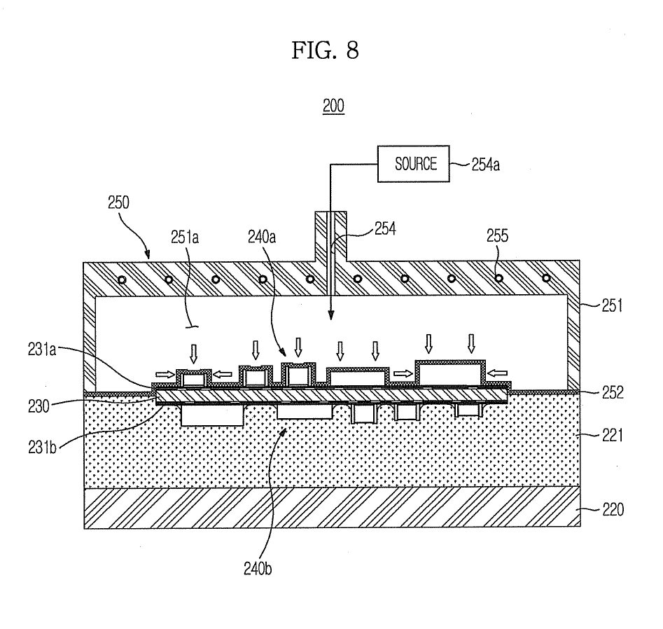

FIG. 7 is a view illustrating a printed circuit board assembly manufacturing device in accordance with example embodiments, and FIG. 8 is a view illustrating a manufacturing process of a printed circuit board assembly using the printed, circuit board assembly manufacturing device of FIG. 7. Hereinafter, some parts illustrated in FIGS. 7 and 8 which are different from those in FIGS. 1 to 6 will be described in more detail.

As shown in FIGS. 7 and 8, a printed circuit board assembly manufacturing device 200 in accordance with example embodiments may include a stage 220 and a fusing unit 250. The printed circuit board assembly manufacturing device 200 may be used to form a printed circuit board assembly by processing a printed circuit board 230 that includes various electronic components 240a and 240b attached thereto via conductive adhesives 231a and 231b. The fusing unit 250 may include a housing 251 and the housing 251 may include heaters 255 in a portion thereof and a pneumatic pressure supply unit 254. Connected to the fusing unit 250 is a pneumatic pressure source 254a which may be used to supply a pressure source fluid to the fusing unit 250. The fusing unit 250 may include a cavity 251a which is enclosed by walls of the fusing unit 250, a top of the fusing unit 250, and a buffer member 252 attached to a bottom of the fusing unit 250.

The stage 220 may include a layer 221 made of a flexible material. The printed circuit board 230 may be supported by the layer 221 of the stage 220.

The various electronic components 240a and 240b may be mounted on both surfaces of the printed circuit board 230. FIG. 7 illustrates a state in which the various electronic components 240a and 240b are bonded to upper and lower surfaces of the printed circuit board 230 by the conductive adhesives 231a and 231b.

In the above state, a pressing process may be performed, as shown in FIG. 8. That is, uniform pressure may be supplied to both surfaces of the printed circuit board 230 provided with the various electronic components 240a and 240b having different heights. In detail, the printed circuit board 230 may be placed on the layer 221 of the stage 220, and the fusing unit 250 may supply heat and pressure to the printed circuit board 230. In example embodiments, when the fusing unit 250 supplies uniform pressure to the upper surface of the printed circuit board 230, the layer 221 of the stage 220 supplies uniform pressure to the lower surface of the printed circuit board 230. In example embodiments, the layer 221 of the stage 220 may be deformed to shapes corresponding to the various electronic components 240b. Further, a Teflon sheet may be provided between the layer 221 of the stage 220 and the various electronic components 240b so as to prevent or reduce bonding of the various electronic components 240b to the layer 221 of the stage 220.

Consequently, the conductive adhesives 231a and 231b may be cured by the supplied heat and pressure, thereby allowing the various electronic components 240a and 240b to be completely mounted on both surfaces of the printed circuit board 230.

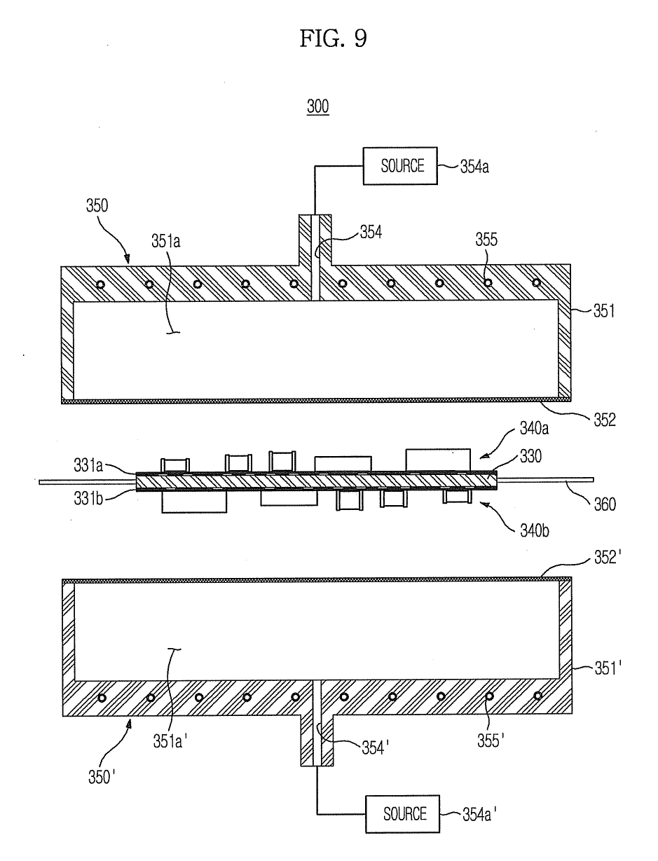

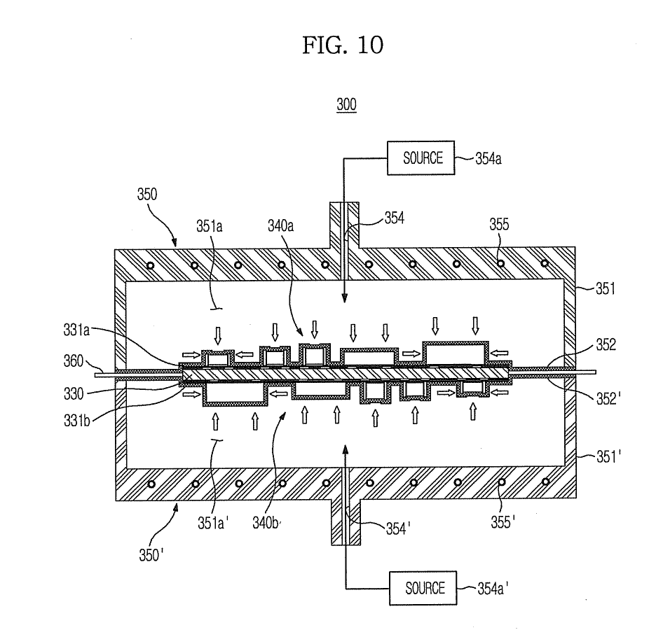

FIG. 9 is a view illustrating a printed circuit board assembly manufacturing device in accordance with example embodiments, and FIG. 10 is a view illustrating a manufacturing process of a printed circuit board assembly using the printed circuit board assembly manufacturing device of FIG. 9. Hereinafter, some parts illustrated in FIGS. 9 and 10 that are different from those illustrated in FIGS. 1 to 8 will be described in more detail.

As shown in FIGS. 9 and 10, a printed circuit board assembly manufacturing device 300 in accordance with example embodiments may include a clamping unit 360 and first and second fusing units 350 and 350′. The clamping unit 360 may be configured to clamp a printed circuit board 330 and the printed circuit board 330 may include various electronic components 340a and 340b secured thereto by conductive adhesives 331a and 331b.

The clamping unit 360 may support the printed circuit board 330. The various electronic components 340a and 340b may be mounted on both surfaces of the printed circuit board 330 supported by the clamping unit 360.

The first fusing unit 350 may be provided above the upper surface of the printed circuit board 330, and the second fusing unit 350′ may be provided below the lower surface of the printed circuit board 330. The first fusing unit 350 and the second fusing unit 350′ may be configured in the same manner or in different manners. That is, each of the first fusing unit 350′ and the second fusing unit 350′ may be one selected from the fusing units shown in FIGS. 1 to 8.

In example embodiments, the first and second fusing units 350 and 350′ may respectively include first and second buffer members 352 and 352′, first and second housings 351 and 351′, first and second heaters 355 and 355′, and first and second pneumatic pressure supply units 354 and 354′. The first and second fusing units 350 and 350′ may also respectively include cavities 351a and 351a′. In example embodiments, pneumatic pressure sources 354a and 354a′ may be respectively connected to the first and second pneumatic pressure supply units 354 and 354′ to apply pressure to the cavities 351a and 351a′. In example embodiments the first and second pneumatic pressure sources 354a and 354a′ may be a same pressure source or different pressure sources.

FIG. 9 illustrates a state in which the various electronic components 340a and 340b are bonded to upper and lower surfaces of the printed circuit board 330 by the conductive adhesives 331a and 331b. In the above state, a pressing process may be performed, as shown in FIG. 10. That is, uniform pressure may be applied to both surfaces of the printed circuit board 330 provided with the various electronic components 340a and 340b having different heights. In detail, the first fusing unit 350 may supply heat and pressure to the upper surface of the printed circuit board 330, and the second fusing unit 350′ may supply heat and pressure to the lower surface of the printed circuit board 330.

Consequently, the conductive adhesives 331a and 331b may be cured by the supplied heat and pressure, thereby allowing the various electronic components 340a and 340b to be completely mounted on both surfaces of the printed circuit board 330.

As is apparent from the above description, a printed circuit board assembly in accordance with example embodiments does not use solder, differing from a conventional SMT process, thereby reducing solder material costs and costs associated with a printing process.

Further, a curing temperature of a conductive adhesive is reduced to be 180° C. or less, and such a low curing temperature is advantageous in an environmental friendly aspect.

Moreover, defects of the printed circuit board, such as warpage, may be prevented or reduced.

Although example embodiments have been shown and described, it would be appreciated by those skilled in the art that changes may be made in example embodiments without departing from the principles and spirit of the invention, the scope of which is defined in the claims and their equivalents.

What is claimed is:

1. A printed circuit board assembly manufacturing device comprising:
a stage configured to support a printed circuit board, the printed circuit board including electronic components having different heights bonded to the printed circuit board by a conductive adhesive; and
a fusing unit configured to simultaneously apply pressure and heat to the printed circuit board to cure the conductive adhesive.

2. The printed circuit board assembly manufacturing device according to claim 1, wherein the fusing unit includes
a buffer member configured to apply a uniform pressure to the electronic components having the different heights, and
elastic particles arranged to press against the buffer member to apply the uniform pressure to the electronic components having the different heights.

3. The printed circuit board assembly manufacturing device according to claim 2, wherein the fusing unit further includes
a housing provided with a cavity in which the elastic particles are provided, and
a pressure member movably provided in the housing, the pressure member being configured to apply pressure to the elastic particles.

4. The printed circuit board assembly manufacturing device according to claim 2, wherein the elastic particles and the buffer member are configured to deform to shapes corresponding to the electronic components having the different heights, and fill gaps between the electronic components having the different heights.

5. The printed circuit board assembly manufacturing device according to claim 3, wherein at least one of the housing and the pressure member includes a heater to supply heat to the conductive adhesive.

6. The printed circuit board assembly manufacturing device according to claim 1, wherein the conductive adhesive includes an Anisotropic Conductive Film (ACF).

7. The printed circuit board assembly manufacturing device according to claim 2, wherein the buffer member includes one of a polymer sheet and a polymer film.

8. The printed circuit board assembly manufacturing device according to claim 1, wherein the fusing unit includes
a buffer member configured to cover and apply a relatively uniform pressure to the electronic components having the different heights, and
a pneumatic pressure supply unit configured to apply pressure to the buffer member.

9. The printed circuit board assembly manufacturing device according to claim 8, wherein the fusing unit further includes a housing with a cavity and the pneumatic pressure supply unit supplies pneumatic pressure to the cavity of the housing.

10. The printed circuit board assembly manufacturing device according to claim 1, wherein the fusing unit includes:
a buffer member configured to cover and apply a relatively uniform pressure to the electronic components having the different heights; and
a hydraulic pressure supply unit configured to apply uniform pressure to the buffer member.

11. The printed circuit board assembly manufacturing device according to claim 10, wherein the fusing unit further includes a housing provided with a cavity and the hydraulic pressure supply unit supplies hydraulic pressure to the cavity of the housing.

12. A printed circuit board assembly manufacturing device comprising:
a stage provided with a layer configured to support a printed circuit board, the printed circuit board including electronic components having different heights bonded to upper and lower surfaces of the printed circuit board by conductive adhesives; and
a fusing unit configured to cure the respective conductive adhesives while simultaneously applying pressure to the electronic components having the different heights bonded to the upper and lower surfaces of the printed circuit board, wherein the layer includes a flexible material.

13. The printed circuit board assembly manufacturing device according to claim 12, wherein the layer is configured to deform to shapes corresponding to the electronic components having the different heights.

14. The printed circuit board assembly manufacturing device according to claim 12, further comprising:
a Teflon sheet between the layer and the electronic components having the different heights.

15. A printed circuit board assembly manufacturing device comprising:
a clamping unit configured to fix a printed circuit board, the printed circuit board having an upper and lower surface, the upper surface including a first plurality of electronic components having different heights bonded thereon by a first conductive adhesive and the lower surface including a second plurality of electronic components having different heights bonded thereon by a second conductive adhesive;
a first fusing unit configured to cure the first conductive adhesive by simultaneously applying pressure and heat to the first plurality of electronic components; and
a second fusing unit configured to cure the second conductive adhesive by simultaneously applying pressure and heat to the second plurality of electronic components.

16. A printed circuit board assembly manufacturing method comprising:
attaching a conductive adhesive to a printed circuit board, the conductive adhesive including a release tape;
bonding electronic components having different heights to the printed circuit board by removing the release paper from the conductive adhesive; and
simultaneously applying pressure to the electronic components having the different heights via elastic particles to cure the conductive adhesive.

17. The printed circuit board assembly manufacturing method according to claim 16, wherein applying pressure includes moving the elastic particles between the electronic components to fill gaps between the electronic components and pressing the elastic particles are deformed to shapes corresponding to the electronic components having different heights.

18. The printed circuit board assembly manufacturing method according to claim 16, wherein heat is supplied to the conductive adhesive a heater.

19. A printed circuit board assembly manufacturing method comprising:
attaching a conductive adhesive to a printed circuit board;
bonding electronic components having different heights to the printed circuit board by removing a release paper from the conductive adhesive; and
simultaneously applying pressure to the electronic components having the different heights through one of a pneumatic and hydraulic, pressure supply unit to cure the conductive adhesive.

20. A printed circuit board assembly manufacturing method comprising:
attaching conductive adhesives to upper and lower surfaces of a printed circuit board;
bonding electronic components having different heights to the upper and lower surfaces of the printed circuit board by removing a release paper from each of the conductive adhesives;
simultaneously applying pressure and heat to the electronic components having the different heights bonded to the upper surface of the printed circuit board through a fusing unit so as to cure the conductive adhesive on the upper surface of the printed circuit board; and
simultaneously applying pressure and heat to the electronic components having the different heights bonded to the lower surface of the printed circuit board through a layer made of a flexible material so as to cure the conductive adhesive on the lower surface of the printed circuit board.

21. A printed circuit board assembly manufacturing method comprising:
bonding electronic components having different heights to upper and lower surfaces of the printed circuit board using conductive adhesives;
simultaneously applying pressure and heat to the electronic components having the different heights bonded to the upper surface of the printed circuit board through a first fusing unit to cure the conductive adhesive on the upper surface of the substrate; and
simultaneously applying pressure and heat to the electronic components having the different heights bonded to the lower surface of the printed circuit board through a second fusing unit to cure the conductive adhesive on the lower surface of the substrate.

22. A printed circuit board assembly comprising:
a printed circuit board;
a conductive adhesive on the printed circuit board; and
electronic components having different heights bonded to the printed circuit board,
wherein the conductive adhesive is cured while simultaneously applying pressure and heat to the electronic components having different heights.
